(19) United States
(12) Patent Application Publication
(10) Pub. No.: US 2005/0253208 A1
(43) Pub. Date: Nov. 17, 2005

(54) Semiconductor micro device

(75) Inventor: Hiroshi Otani, Tokyo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Mitsubishi Denki Kabushiki Kaisha, Tokyo (JP)

(21) Appl. No.: 11/079,876

(22) Filed: Mar. 15, 2005

(30) Foreign Application Priority Data
May 13, 2004 (JP) 2004-143035

(51) Int. Cl. H01L 23/495

(52) U.S. Cl. 257/415; 257/676

(57) ABSTRACT

A semiconductor micro device is provided with a rectangular silicon micro structure chip; a lead frame having a die pad for securing the silicon structure chip comprising a contact portion with the chip; and a resin encapsulating material for encapsulating the silicon structure chip and part of the lead frame; wherein the die pad of the lead frame has a non-contact portion positioned lower than the contact portion not to be in contact with the silicon structure chip, the non-contact portion being formed at least in a position corresponding to a diagonal portion of the silicon structure chip. A clearance between the non-contact portion and the silicon structure chip is filled with the resin encapsulating material, whereby the die pad and the silicon structure chip are bonded to each other by the resin encapsulating material.

### BACKGROUND OF THE INVENTION

1. Field of the Invention

The present invention relates generally to resin-encapsulated semiconductor micro devices each having a silicon micro structure chip, and more particularly to a micro device capable of relieving thermal strain potentially imposed on a silicon structure chip.

2. Description of the Related Art

Silicon micro structure chips having micro movable components are used as, for example, acceleration sensors and angular acceleration sensors for sensing accelerations of motor vehicles, aircrafts, and the like; and electrostatic actuators formed by utilizing micro-processing techniques. For example, a sensor chip for an acceleration sensor has a cantilevered movable portion and a static portion disposed in proximity to the movable portion. When operation enters an acceleration state, the movable portion of the sensor chip finely moves to sense a fine distance transition between the movable portion and the static portion as a resistance transition. In this manner, the acceleration is detected.

The silicon structure chips of the above-described type are used by being adhered to a chip-mounting table. Ordinarily the silicon structure chip and the mounting table are formed of different materials having different thermal expansion coefficients. When the temperature rises, a difference in thermal expansion between the silicon structure chip and the mounting table is generated. The thermal expansion difference causes tensile stress or compression stress in the silicon structure chip, thereby potentially leading to distortion, that is, thermal strain of the chip. With advances in miniaturization technology in the field of silicon structure chip s, even fine thermal strain causes a critical problem in that the silicon structure chip erroneously operates.

Japanese Unexamined Patent Publication No. 2001-208627 discloses a method of, solving a problem of thermal strain potentially imposed on a chip. Specifically, in a semiconductor pressure detector, a sensor chip formed of a glass pedestal and a silicon diaphragm is secured on a hermetic glass. In the pressure detector, a circular projection portion having an area smaller than the area of a bonded side of the sensor chip is formed on the sensor chip or the hermetic glass. A surface of the projection portion is used as a bonding face. In comparison to a case where the projection portion is not formed, the bonding area between the sensor chip and the hermetic glass is reduced. Accordingly, the degree of thermal strain directly imposed on by the sensor chip through the bonding face of the sensor chip is reduced. In addition, since a non-secure chip region other than a secure region on the surface of the projection portion is not in contact with the hermetic glass, thermal strain is not imposed on the non-secure chip region.

In addition, Japanese Unexamined Patent Publication No. 06-289048 discloses a capacitance-type acceleration sensor including a sensor chip and an alumina base plate for securing the sensor chip. The sensor chip is configured such that a silicon movable electrode layer is interposed between two glass secure electrode layers. Similar to the above, the publication discloses that, to relieve the thermal strain, a projection portion having an area smaller than the area of a bonded side of the sensor chip is formed on the sensor chip or the base plate. Additionally, instead of the projection portion, a spacer having an area smaller than the area of the bonded side of the sensor chip can be interposed between the sensor chip and the base plate. Since the projection portion is bonded via the spacer, the boding area is reduced, so that thermal strain potentially imposed on the sensor chip can be reduced.

By way of another embodiment according to this publication, a natural rubber-type adhesive material is used as a bonding layer positioned between the sensor chip and the base plate. In this case, the bonding layer serves to relieve the internal stress, thereby relieving the thermal strain potentially imposed on the sensor chip.

Recently, from the viewpoint of easy handling, demands arise in that the semiconductor micro device is provided in the form of a resin-encapsulated IC chip. Such an IC-chip type micro device is fabricated in such a manner that a silicon sensor chip is secured on a die pad of a metal lead frame, and the device is molded with a resin encapsulating material. In the semiconductor micro device, however, the entirety of the silicon structure chip is in contact with the die pad or the resin encapsulating material. As such, in comparison to a conventional non-resin-encapsulated micro device, the state and distribution of thermal strain potentially imposed on the silicon structure chip are more intricate. For this reason, in the encapsulated micro device, the thermal strain cannot be sufficiently relieved or removed by the conventional method.

Further, in an ordinary resin-encapsulated micro device, the lead frame is formed of a thin copper film, and the semiconductor chip is formed of silicon. As such, the difference between the linear expansion coefficient of the lead frame and the linear expansion coefficient of the semiconductor chip sensor is as large as about five times. This difference is significantly exceeds the difference in linear expansion coefficient between the chip mounting table and the sensor chip in the each case disclosed in the above-described patent publications. As a result, the difference of the encapsulated micro device implies that thermal strain potentially imposed on the sensor chip is significantly higher. Therefore, in a case where a projection portion is formed by using the conventional techniques, the boding area of the surface of the projection portion needs to be very small in order to essentially remove the thermal strain. In this case, however, since the sensor chip cannot be securely boded with die (“die-bonded”, hereafter), the chip is shaky during the manufacturing, thereby potentially leading to an increase of a defective-product occurrence rate.

### SUMMARY OF THE INVENTION

An object of the present invention is to provide a high performance and high-reliability resin-encapsulated semiconductor micro device that has a less effect of thermal strain on a sensor chip.

An object of the present invention is to provide a semiconductor micro device having a lead frame that allows secure die-bonding during the manufacturing.

The present invention is a semiconductor micro device comprising: a rectangular silicon microstructure chip; a lead frame having a die pad for securing the silicon structure chip comprising a contact portion being in contact with the silicon structure chip; and a resin encapsulating material for encapsulating at least portions of the silicon structure chip and the lead frame. The die pad of the lead frame has a die-bond region for mounting the structure chip. The die-bond region has a non-contact portion not to be in contact with the silicon structure chip.

The contact portion is a portion for supporting the structure chip, and the structure chip is die-bonded to the contact portion.

The non-contact portion is a stepped portion formed lower than the contact portion, and is a portion not in contact with the structure chip when the structure chip is die-bonded to the contact portion. A clearance between the non-contact portion and the structure chip is filled with the resin material in a resin encapsulation step. In the state where the semiconductor micro device is finished in manufacture, the entirety of the structure chip is supported and secured by the contact portion and the resin material filled in the clearance between the non-contact portion and the structure chip.

In the present invention, it was discovered that, with the contact portion of the die pad being formed along the direction of diagonal line of the rectangular structure chip, thermal strain of the structure chip tends to increase. Therefore, the die pad of the lead frame used in the present invention is designed to reduce the area of contact portion that are to be formed in a position corresponding to the diagonal line of the structure chip. Consequently, in the die pad used in the present invention, the non-contact portion is formed in a portion or the entirety of the region corresponding to the diagonal line of the structure chip.

According to the present invention, the area of the contact portion formed in a position corresponding to the diagonal line of the structure chip is reduced, whereby the thermal strain potentially imposed on the structure chip is reduced. Thereby, a high-reliability semiconductor micro device can be obtained.

The non-contact portion is filled with the resin encapsulating material by the resin encapsulation step. As a result, in the state where the semiconductor micro device is manufactured into a final product, the structure chip therein is not only supported by the contact portion, but is also supported by the resin encapsulating material. Consequently, compared with a semiconductor micro device wherein the clearance remains in the non-contact portion without encapsulation by resin material, impact resistance of the structure chip of the present invention is improved.

### BRIEF DESCRIPTION OF THE DRAWINGS

The present invention will be described in greater detail with reference to the accompanying drawings, wherein:

FIGS. 1A and 1B show schematic views of a semiconductor micro device according to the present invention;

FIG. 2A is a top view of a die pad and a sensor chip of a micro device according to a first embodiment of the present invention;

FIG. 2B is a cross-sectional view of the micro device shown along the line A-A of FIG. 2A;

FIG. 3A is a top view of a die pad and a sensor chip of a micro device according to a modified example of the first embodiment of the present invention;

FIG. 3B is a cross-sectional view of the micro device shown along the line A-A of FIG. 3A;

FIG. 4A is a top view of a die pad and a sensor chip of a micro device according to a second embodiment of the present invention;

FIG. 4B is a cross-sectional view of the micro device shown along the line A-A of FIG. 4A;

FIG. 5A is a top view of a die pad and a sensor chip of a micro device according to a modified example of the second embodiment of the present invention;

FIG. 5B is a cross-sectional view of the micro device shown along the line A-A of FIG. 5A;

FIG. 6A is a top view of a die pad and a sensor chip of a micro device according to another modified example of the second embodiment of the present invention;

FIG. 6B is a cross-sectional view of the micro device shown along the line A-A of FIG. 6A;

FIG. 7A is a top view of a die pad and a sensor chip of a micro device according to a third embodiment of the present invention;

FIG. 7B is a cross-sectional view of the micro device shown along the line A-A of FIG. 7A;

FIG. 8A is a top view of a die pad and a sensor chip of a micro device according to a modified example of the third embodiment of the present invention;

FIG. 8B is a cross-sectional view of the micro device shown along the line A-A of FIG. 8A;

FIG. 9A is a top view of a die pad and a sensor chip of a micro device according to another modified example of the third embodiment of the present invention;

FIG. 9B is a cross-sectional view of the micro device shown along the line A-A of FIG. 9A;

FIG. 10A is a top view of a die pad and a sensor chip of a micro device according to a fourth embodiment of the present invention;

FIG. 10B is a cross-sectional view of the micro device shown along the line A-A of FIG. 10A;

FIG. 11A is a top view of a die pad and a sensor chip of a micro device according to a modified example of the fourth embodiment of the present invention;

FIG. 11B is a cross-sectional view of the micro device shown along the line A-A of FIG. 11A;

FIG. 12A is a top view of a die pad and a sensor chip of a micro device according to a fifth embodiment of the present invention;

FIG. 12B is a cross-sectional view of the micro device shown along the line A-A of FIG. 12A;

FIG. 13A is a top view of a die pad and a sensor chip of a micro device according to a modified example of the fifth embodiment of the present invention; and

FIG. 13B is a cross-sectional view of the micro device shown along the line A-A of FIG. 13A.

### DETAILED DESCRIPTION OF THE PREFERRED EMBODIMENTS

A semiconductor micro device of the present invention includes a rectangular silicon microstructure chip having a movable portion; a lead frame having die pad for securing the silicon structure chip; a resin encapsulating material for encapsulating the silicon structure chip and a part of the lead frame. The die pad includes a contact portion that is in contact with the silicon structure chip and that thereby supports the silicon structure chip; and a non-contact portion that is not contact with the silicon structure chip. In the semiconductor micro device, the non-contact portion is formed in at least a position corresponding to a diagonal line of the silicon structure chip. The resin encapsulating material is filled between the non-contact portion and the silicon structure chip.

The lead frame made of a copper foil sheet or the like is formed by press forming or etching. The lead frame has a die pad, inner leads, and outer leads. A semiconductor chip, such as the silicon structure chip, is die-bonded to the die pad and is rendered in electrically communication with the inner leads by, for example, wire bonding. The outer leads are press formed and bent in conformity with standards for sockets and electrodes to which the semiconductor micro device is attached.

For the resin encapsulating material, a material is selected that is excellent in insulating property, high-frequency property, strength, adhesion strength, moisture resistance, and formability. Particularly, a material that is excellent in the aforementioned properties under high temperature is selected. An epoxy resin is usable for the resin encapsulating material.

The non-contact portion is preferably formed in a position corresponding to each of four corner portions of the silicon structure chip for the reason that thermal strain potentially imposed on the diagonal line of the silicon structure chip can be even more reduced.

The contact portion is preferable formed in a position corresponding to the center portion of the chip. It can suppress the center portion of the structure drooping from its own weight and bending the entire silicon structure chip.

Ordinarily, a silicon structure chip has bonding pads for wire bonding, wherein the silicon structure chip is connected to either another semiconductor chip or the inner leads by wire bonding. For the present invention, the non-contact portion of the die pad is preferably not formed in a position corresponding to a position where the bonding pads of the silicon structure chip are formed. This is because the contact portion supports stresses imposed on the silicon structure chip during wire bonding, thereby to enable preventing an event where the silicon structure chip is bent during wire bonding. In addition, the above is preferable because effects can be expected in that wobbling of the silicon structure chip during wire bonding is reduced, thereby to enable restraining occurrence of defective products due to, for example, bonding error and/or wire cutting.

The contact portions and the non-contact portions should be designed to be capable of steadily supporting the silicon structure chip after die bonding. Preferable forming positions of the contact portions are positions, such as four corner portions of the chip, side portions of the chip, and central portions of the chip, where balancing can easily be achieved. This is because even when the area of the contact portion is reduced to decrease the thermal strain effects, the chip can be steadily supported.

The contact portion may be formed into an arbitrary shape, such as a slender beam shape, circular shape, elliptical shape, triangular shape, rectangular shape, point shape, or the like, or a combined shape thereof.

The non-contact portion may be a recess portion and/or cut-formed portion. The recess portion is a portion formed such that a recess is formed in a die pad surface on the side where the silicon structure chip is die-bonded to reduce the thickness of the die pad. The recess portion is formed by conventionally known techniques, such as etching including dry etching or wet etching, and die-used press forming. When the silicon structure chip is die-bonded to the die pad, the silicon structure chip and the recess portion are partially spaced apart from each other. Thereafter, when molding is performed by using the resin encapsulating material, the resin encapsulating material fills into the recess portion through the space between the silicon structure chip and the recess portion. Thereby, the recess portion and the silicon structure chip are bonded together-through the resin encapsulating material.

When a bottom portion of the recess portion is expanded by thermal expansion, the thermal strain transfers to the silicon structure chip through the resin encapsulating material. However, since the resin material is softer than metal, the thermal strain is relieved while transferring through the resin encapsulating material. When having arrived at the silicon structure chip, the thermal strain is sufficiently reduced. Accordingly, compared with a semiconductor micro device without the recess portion, in the semiconductor micro device having the recess, the thermal strain effect is apparently relieved. With the lead frame wherein the recess portion is formed in the die pad suface, a strength substantially the same as a conventional lead frame can be maintained.

The cut-formed portion is a through-opening provided in the die pad by, for example, punching or etching. The cut-formed portion is formed by removing a metal portion causing the thermal strain. Accordingly, the cut-formed portion is effective to restrain the thermal strain potentially imposed on the silicon structure chip. However, since the lead frame is formed of a very thin metal sheet, an undesired case can occur in which the strength of the lead frame is excessively reduced by providing the cut-formed portion in the die pad. However, in the configuration where molding is performed to fill the cut-formed portion with the resin encapsulating material, the strength reduction resulting from the cut-formed portion can be compensated for by the resin. Consequently, no problems take place in a final product stage. From this viewpoint, design is preferably performed to provide strength not causing deformation during manufacturing steps before molding. For example, such a die pad-strength problem can be solved in a manner that a reinforcing portion is provided not to easily cause deformation of the cut-formed portion, and the lead frame is supported by a sub-plate before the molding. If a lead frame has a large thickness or is formed of a high strength material, even in the configuration where the cut-formed portion is formed, a sufficient strength can be maintained. As such, the lead frame is suitable for forming the cut-formed portion.

First Embodiment

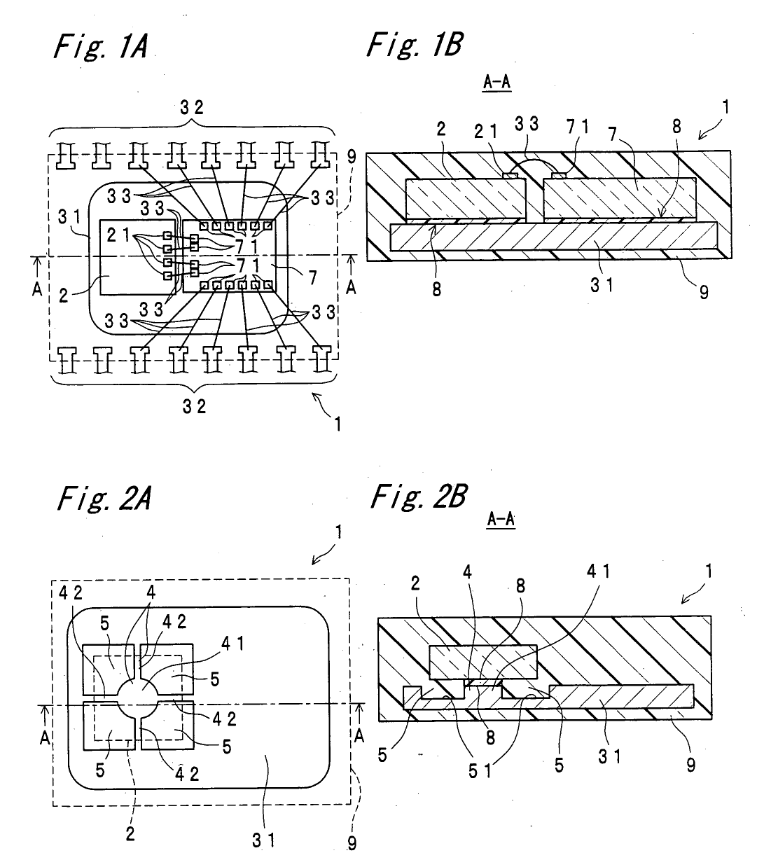

FIGS. 1A and 1B show schematic views of a resin-encapsulated semiconductor micro device 1. A sensor chip 2 as a silicon structure chip having a movable portion, and a semiconductor chip 7 (application specific integrated circuit (ASIC)) are die-bonded on a die pad 31 of a lead frame. The sensor chip 2 and the semiconductor chip 7 are electrically connected to each other by wires 33 through bonding pads 21 and 71 provided on the surfaces of the sensor chip 2 and the semiconductor chip 7 respectively. Further, the semiconductor chip 7 is electrically connected by wires 33 to inner leads 32 of the lead frame. The sensor chip 2, the semiconductor chip 7, the die pad 31, and the inner leads 32 are molded of a resin encapsulating material 9 and thereby hermetically sealed from the outside.

FIG. 2A is view of a first embodiment of the semiconductor micro device according to the present invention. More specifically, FIG. 2 mainly shows configurations of a sensor chip 2 and a die pad 31, wherein a semiconductor chip 7 and inner leads 32 are not shown.

On a surface of the die pad 31, there are formed a contact portion 4 for supporting the sensor chip 2, and recess portions 5 formed by etching about half the thickness of the die pad 31.

The contact portion 4 is formed of a circular center support portion 41 positioned in the center of the sensor chip 2; and four beam support portions 42 extending in four directions from the center support portion 41. In the shown example, although the center support portion 41 is formed circular, the center support portion 41 may be formed into an arbitrary shape such as a polygonal shape like a rectangular shape, or an elliptical shape. In the shown example, although extending to four directions substantially perpendicular to two sides of the sensor chip 2, the beam support portions 42 may be each formed to extend in any of arbitrary directions, except a diagonal-line direction of the sensor chip 2. By way of a modified example, three beam support portions 42 may be formed individually to extend in three directions from the center support portion 41.

With reference to FIG. 2A, the substantially rectangular recess portion 5 are disposed in four (vertical 2×horizontal 2) portions, wherein the beam support portions 42 are each disposed between the two recess portions 5. The center support portion 41 is positioned in substantially the center of the regions where the four recess portions 5 are formed, so that one corner portion of the respective recess portion 5 is shaped in the form of a cutout sector.

The maximum size of the region where the four recess portions 5 is preferably larger than the size of the sensor chip 2. With the configuration thus formed, a clearance (or, space distance) between an edge portion of the sensor chip 2 and the die pad 31 can be set large, thereby further lowering thermal strain imposed on the sensor chip 2. As shown in FIG. 2, when observed from over the sensor chip 2, parts of the recess portions 5 are seen as to surround the periphery of the sensor chip 2. In molding, the resin encapsulating material 9 feeds in the recess portions 5 from clearances between the recess portions 5 and the sensor chip 2 to fill the regions between the recess portions 5 and the sensor chip 2.

The recess portions 5 may be formed using a known technique, such as dry etching or wet etching.

FIG. 2B is a cross-sectional of the micro device 1 shown along the line A-A of FIG. 2A after resin encapsulation. In the shown cross sectional, the sensor chip 2 is die-bonded to the center support portion 41 of the die pad 31, and the recess portions 5 are filled with the resin encapsulating material 9.

With reference to FIG. 2B, as the depth of the respective recess portion 5 is larger, the thickness of the resin encapsulating material 9 interposed between the bottom portion 51 of the respective recess portion 5 and the sensor chip 2 is proportionally larger. As the thickness of the resin encapsulating material 9 is larger, the relief degree of thermal strain potentially transferring to the sensor chip 2 from a bottom portion 51 is proportionally larger. Accordingly, as the depth of the recess portion 5 is larger, the effect of reducing the thermal strain potentially imposed thereon is proportionally enhanced. However, with an increased depth of the recess portion 5, the time and costs required for etching are increased. It is preferable that the depth of the respective recess portions 5 be set to fall within a tolerable range of the thermal strain potentially imposed on the chip.

A manufacturing process for the semiconductor micro device according to the present invention includes: forming predetermined recess portions 5 and a predetermined support portion 4 on a die pad 31 of a wire frame; die-bonding a sensor chip 2 to a part or the entirety of the contact portion 4 the die pad 31; and molding the sensor chip 2, the die pad 31, and a part of the inner leads 32 by using the resin encapsulating material 9.

In the step of die-bonding the sensor chip 2, the sensor chip 2 may be die-bonded only to the center support portion 41. In that case, the four beam support portions 42 are set to support a bottom portion of the sensor chip 2 to horizontally position the sensor chip 2.

In the step of molding, the resin encapsulating material 9 is filled into the individual clearances between the recess portions 5 and the sensor chip 2. After molding, also individual clearances between the beam support portions 42 and the sensor chip 2 are secured with the resin encapsulating material 9.

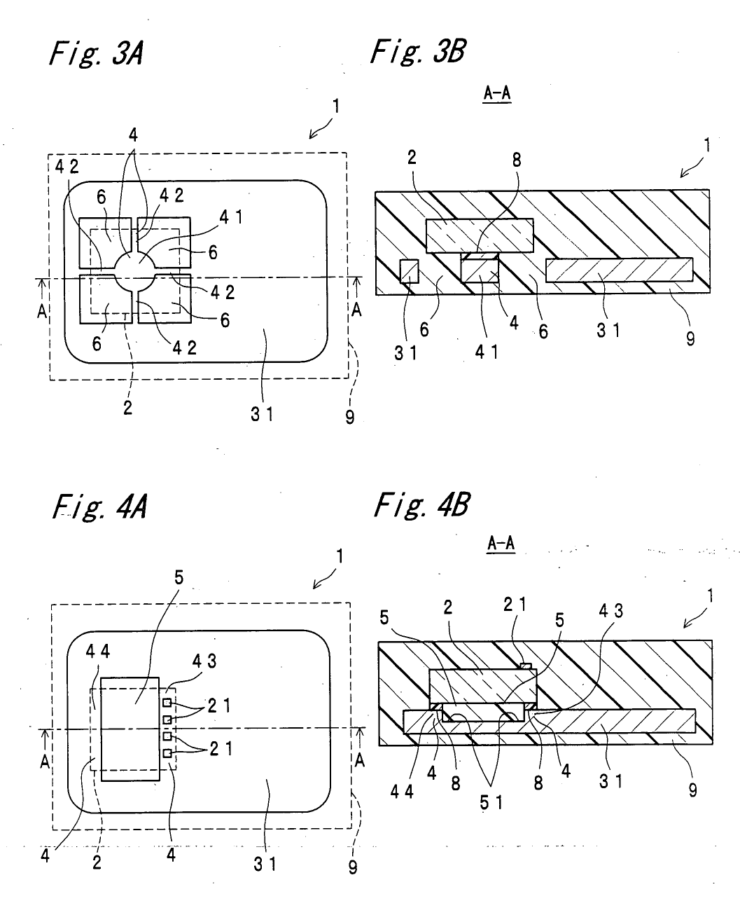

FIG. 3A shows a micro device 1 by way of a modified example of the above-described present embodiment, wherein instead of the recess portions 5, cut-formed portions 6 are formed in the die pad 31. In this modified example, the contact portion 4 is formed into the same shape as that of the contact portion 4 shown in FIG. 2A. The cut-formed portions 6, each being substantially rectangular, are individually formed in four portions of the surface of the die pad 31. The cut-formed portions 6 may be formed by a known technique, such as punching, cutting, dry etching, or wet etching, for example.

FIG. 3B is a cross-sectional view of the micro device 1 shown along the line A-A of FIG. 3A after resin capsulation. In the configuration of the shown cross-sectional view, the sensor chip 2 is die-bonded to the center support portion 41 of the die pad 31. The cut-formed portions 6 are filled with the resin encapsulating material 9.

As can be seen from FIG. 3B, the cut-formed portions 6 do not impose the thermal strain on the sensor chip 2, therefore rendering the performance of the sensor chip 2 to be more steady than the embodiment shown in FIG. 2. However, in the present embodiment, the contact portion 4 is completely formed like a brattishing, thereby to reduce the strength of the lead frame. As such, in a step such as the step of die-bonding where a load is imposed on the lead frame, care should be taken in handling.

Second Embodiment

FIG. 4A is view of a second embodiment of the semiconductor micro device according to the present invention. More specifically, FIG. 4A mainly shows configurations of a sensor chip 2 and a die pad 31, wherein a semiconductor chip 7 and inner leads 32 are not shown. The sensor chip 2 used in the present embodiment is shaped to be electrically communicable with another semiconductor chip 7 by wire bonding. In the shown sensor chip 2, four bonding pads 21 for wire bonding are formed on the upper surface of the sensor chip 2 along one side of the rectangle whereon the sensor chip 2.

A contact portion 4 for supporting the sensor chip 2 and a recess portion 5 formed by etching about half the thickness of the die pad 31 are formed on the surface of the die pad 31.

The contact portion 4 is constituted of two portions. One is a pad support portion 43 that supports a bottom portion of one side (right side of the chip, as viewed in FIG. 4A), along which the bonding pads 21 are formed, of four sides forming the edge portion of the sensor chip 2. The other is an opposite-side support portion 44 for supporting a bottom portion of an opposite side (left side of the chip, as viewed in FIG. 4A) opposing the above-described one side of the sensor chip 2.

The pad support portion 43 is capable of supporting stresses being imposed on the bonding pads 21 of the sensor chip 2, therefore enabling suppressing an event where the chip is tilted by stresses occurring during wire bonding.

In cooperation with the pad support portion 43, the opposite-side support portion 44 steadily supports the sensor chip 2 in the duration from die-bonding of the sensor chip 2 to the molding.

In the configuration shown in FIG. 4A, the substantially rectangular recess portion 5 is formed. The form width (horizontal width) of the recess portion 5, that is, the distance between the pad support portion 43 and the opposite-side support portion 44, is set smaller than the form width of the sensor chip 2. Thereby, left and right edge portions of the sensor chip 2 can be die-bonded and secured thereby to the pad support portion 43 and the opposite-side support portion 44. A form length (vertical length) of the recess portion 5 is preferably set larger than a form length of the sensor chip 2. In the configuration thus formed, the upper and lower sides of the sensor chip 2 and the clearance from the die pad 31 can be set relatively longer, so that the thermal strain being potentially being imposed on the sensor chip 2 can be even more reduced.

As is shown in FIG. 4A, when observed from over the die pad 31, parts of the recess portion 5 are seen in outer portions of the upper and lower sides of the sensor chip 2. In molding, the resin encapsulating material 9 feeds in the recess portion 5 from clearance between the recess portion 5 and the sensor chip 2, whereby to fill the region between the recess portion 5 and the sensor chip 2.

The recess portion 5 can be formed by using a known technique, such as dry etching or wet etching.

FIG. 4B is a cross-sectional view of the micro device 1 shown along the line A-A of FIG. 4A after resin capsulation. In the shown cross section, the sensor chip 2 is die-bonded to the pad support portion 43 and opposite-side support portion 44 of the die pad 31. The recess portion 5 is filled with the resin encapsulating material 9.

With reference to FIG. 4B, as the depth of the respective recess portion 5 is larger, the thickness of the resin encapsulating material 9 interposed between the bottom portion 51 of the recess portion 5 and the sensor chip 2 is proportionally larger. As the thickness of the resin encapsulating material 9 is larger, the relief degree of the thermal strain potentially transferring to the sensor chip 2 from a bottom portion 51 is proportionally larger. Accordingly, as the depth of the recess portion 5 is larger, the effect of reducing the thermal strain potentially imposed thereon is proportionally enhanced. However, with an increased depth of the recess portion 5, the time and costs required for etching are increased. It is preferable that the depth of the respective recess portion 5 be set to fall within a tolerable range of the thermal strain potentially imposed on the chip.

A manufacturing process for the semiconductor micro device according to the present invention includes: forming a predetermined recess portion 5 and a predetermined support portion 4 on a die pad 31 of a wire frame; die-bonding a sensor chip 2 to a part or the entirety of the contact portion 4 of the die pad 31; wire bonding the sensor chip 2 to, for example, another semiconductor chip 7; and molding the sensor chip 2, the die pad 31, and the inner leads 32 by using the resin encapsulating material 9.

Regularly, in the step of die-bonding the sensor chip 2, the sensor chip 2 is die-bonded to the pad support portion 43 and the opposite-side support portion 44. Thereby, the sensor chip 2 is steadily supported till the step of molding.

In the step of molding, the resin encapsulating material 9 is filled into the clearance between the recess portion 5 and the sensor chip 2.

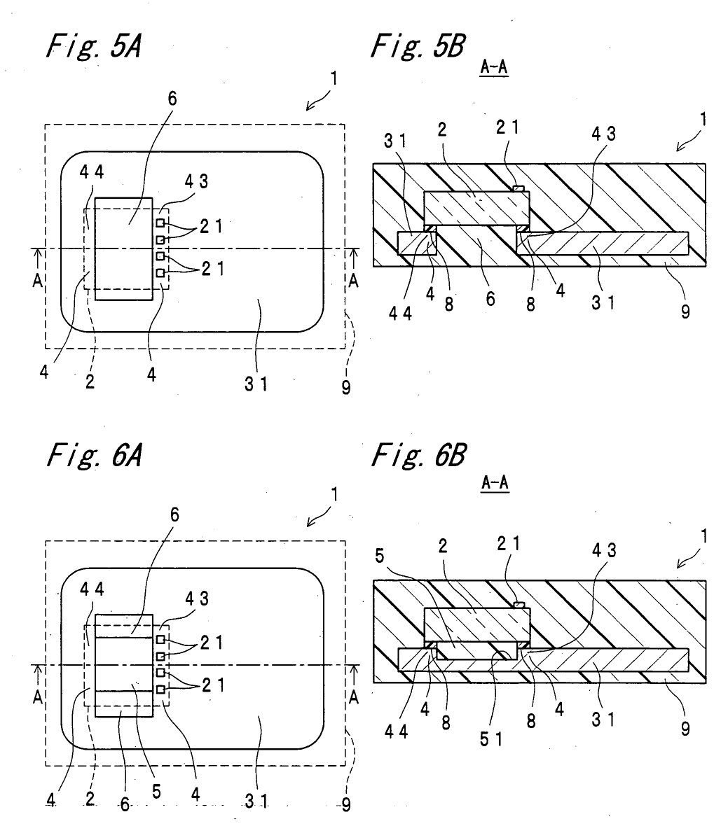

FIG. 5A shows a micro device 1 by way of a modified example of the above-described present embodiment, wherein instead of the recess portion 5, a cut-formed portion 6 is formed in the die pad 31. In this modified example, the contact portion 4 is formed into the same shape as that of the contact portion 4 shown in FIG. 4A. The cut-formed portion 6 in a rectangular shape is formed on the surface of the die pad 31. The cut-formed portion 6 may be formed by a known technique, such as punching, cutting, dry etching, or wet etching, for example.

FIG. 5B is a cross-sectional view of the micro device 1 shown along the line A-A of FIG. 5A after resin capsulation. In the shown cross section, the sensor chip 2 is die-bonded to the pad support portion 43 and opposite-side support portion 44 of the die pad 31. The cut-formed portion 6 is filled with the resin encapsulating material 9.

As can be seen from FIG. 5B, the cut-formed portion 6 does not impose thermal strain on the sensor chip 2, therefore rendering the performance of the sensor chip 2 to be more steady than the embodiment shown in FIG. 4A. Nevertheless, however, the cut-formed portion 6 reduces the strength of the lead frame. As such, in a step such as the step of die-bonding where a load is imposed on the lead frame, care should be taken in handling.

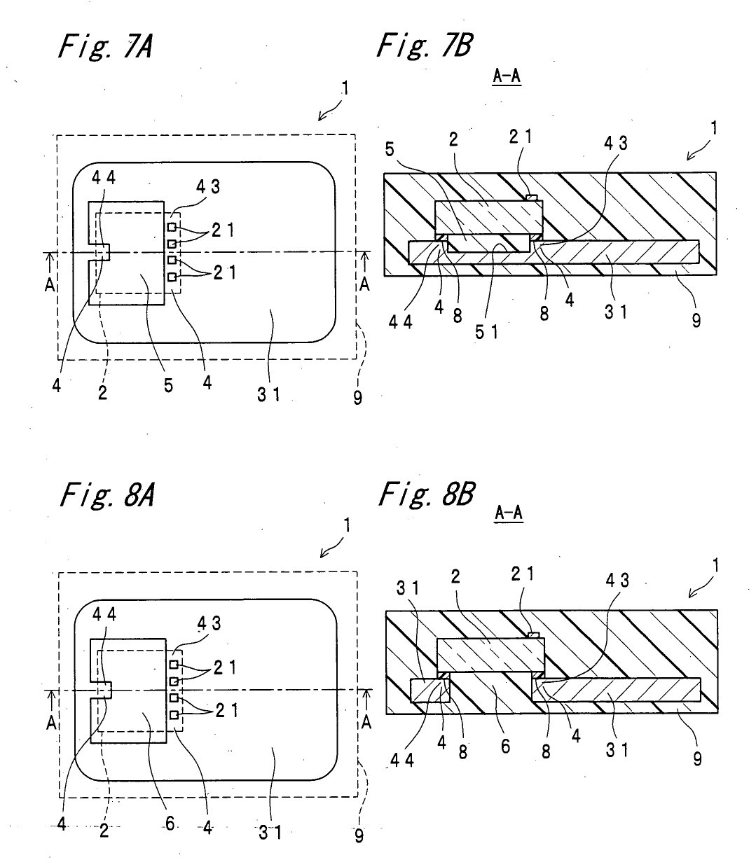

FIGS. 6A and 6B show another modified example of the micro device 1 of the present embodiment. In the modified example, a non-contact portion has a combination feature of a recess portion 5 and cut-formed portions 6. In the non-contact portion, upper and lower portions are the cut-formed portions 6, and the recess portion 5 is formed between the cut-formed portions 6. Similar to the configurations shown in FIGS. 4A and 5A, the contact portion 4 is formed of the pad support portion 43 and the opposite-side support portion 44. A feature, among others, of the modified example is that, compared with the configuration in FIG. 4A, since the cut-formed portions 6 are disposed, the thermal-strain reduction effect is high. Another feature is that, compared with the configuration shown in FIG. 5A, since the recess portion 5 is disposed, the lead frame strength is high.

The dispositions of the cut-formed portions 6 and the recess portion 5 in the non-contact portion are not limited to those in FIG. 6A. For example, the configuration may be such that the cut-formed portions 6 are formed in left and right portions in the horizontal direction, and the recess portion 5 is formed between the cut-formed portions 6. Alternatively, the configuration may be such that the cut-formed portions 6 and the recess portion 5 are disposed in a stripe state. Still alternatively, the configuration may be such that recess portions 5 are formed along the vertical and horizontal direction in a lattice state, wherein a region surrounded by the recess portions 5 is used as a cut-formed portion 6.

Third Embodiment

FIG. 7A is view of a third embodiment of the semiconductor micro device according to the present invention. More specifically, FIG. 7A mainly shows configurations of a sensor chip 2 and a die pad 31, wherein a semiconductor chip 7 and inner leads 32 are not shown. The sensor chip 2 used in the present embodiment is shaped to be electrically communicable with another semiconductor chip 7 by wire bonding, as in the case of FIG. 1A. In the shown sensor chip 2, four bonding pads 21 for wire bonding are formed on the upper surface of the sensor chip 2 along one side of the rectangle whereon the sensor chip 2.

A contact portion 4 for supporting the sensor chip 2 and a recess portion 5 formed by etching about half the thickness of the die pad 31 are formed on the surface of the die pad 31.

The contact portion 4 is constituted of two portions. One is a pad support portion 43 that supports a bottom portion of one side (right side of the chip, as viewed in FIG. 7A), along which the bonding pads 21 are formed, of four sides forming the edge portion of the sensor chip 2. The other is an opposite-side support portion 44 for supporting a bottom portion of an opposite side (left side of the chip, as viewed in FIG. 7A) opposing the above-described one side of the sensor chip 2. Compared with the embodiment shown in FIGS. 4A and 4B, the opposite-side support portion 44 is different in shape.

The pad support portion 43 is capable of supporting stresses being imposed on the bonding pads 21 of the sensor chip 2, therefore enabling suppressing an event where the chip is tilted by stresses occurring during wire bonding.

In cooperation with the pad support portion 43, the opposite-side support portion 44 steadily supports the sensor chip 2 in the duration from die-bonding of the sensor chip 2 to the molding process. The opposite-side support portion 44 according to the present embodiment is formed to have a smaller area as compared to the embodiment shown in FIGS. 4A and 4B. However, while steady-supporting capability is somewhat reduced, the thermal strain potentially imposed on the sensor chip 2 can be lowered.

In the configuration shown in FIG. 7A, the recess portion 5 is formed such that a small, substantially rectangular projection portion (opposite-side support portion 44) is formed on the left side of a substantially rectangular shape. A minimum form width (minimum horizontal width) of the recess portion 5, that is, the distance between the pad support portion 43 and the opposite-side support portion 44, is set smaller than the form width the sensor chip 2. Thereby, left and right edge portions of the sensor chip 2 can be die-bonded and secured thereby to the pad support portion 43 and the opposite-side support portion 44. A maximum form width of the recess portion 5 is a form width in the case where the opposite-side support portion 44 is excluded. In the case shown in FIG. 7A, a maximum form width of the recess portion 5 is set substantially identical to the chip form width. However, the maximum form width is not limited thereto. In the event of die-bonding of the sensor chip 2, the maximum form width may be altered so that a portion of the left side section of the recess portion 5, in which the opposite-side support portion 44 is not formed, is spaced away from the sensor chip 2. In the configuration thus formed, the left side of the sensor chip 2 and the die pad 31 can partly be spaced away from each other, so that the thermal strain potentially imposed on the sensor chip 2 can be even more reduced.

The form length (vertical length) of the recess portion 5 is preferably set larger than the form length of the sensor chip 2. In the configuration thus formed, the upper and lower sides of the sensor chip 2 the clearance from the die pad 31 can be set relatively longer, so that the thermal strain being potentially being imposed can be even more reduced.

As is shown in FIG. 7A, when observed from over the die pad 31, partial sections of the recess portion 5 are seen in outer portions of the upper and lower sides of the sensor chip 2 and an outer partial section of the left side thereof (portions where the opposite-side support portion 44 is not in contact). In molding, the resin encapsulating material 9 feeds in the recess portion 5 from clearance between the recess portion 5 and the sensor chip 2, whereby to fill the region between the recess portion 5 and the sensor chip 2.

The recess portion 5 can be formed by using a known technique, such as dry etching or wet etching.

FIG. 7B is a cross-sectional view taken along the line A-A of the micro device of FIG. 7A after resin encapsulation. In the shown cross section, the sensor chip 2 is die-bonded to the pad support portion 43 and opposite-side support portion 44 of the die pad 31. The recess portion 5 is filled with the resin encapsulating material 9.

With reference to FIG. 7B, as the depth of the respective recess portion 5 is larger, the thickness of the resin encapsulating material 9 interposed between the bottom portion 51 of the recess portion 5 and the sensor chip 2 is proportionally larger. As the thickness of the resin encapsulating material 9 is larger, the relief degree of the thermal strain potentially transferring to the sensor chip 2 from a bottom portion 51 is proportionally larger. Accordingly, as the depth of the recess portion 5 is larger, the effect of reducing the thermal strain potentially imposed thereon is proportionally enhanced. However, with an increased depth of the recess portion 5, the time and costs required for etching are increased. It is preferable that the depth of the respective recess portion 5 be set to fall within a tolerable range of the thermal strain potentially imposed on the chip.

A manufacturing process for the semiconductor micro device according to the present invention includes: forming a predetermined recess portion 5 and a predetermined support portion 4 on a die pad 31 of a wire frame; die-bonding a sensor chip 2 to a partial section or the entirety of the contact portion 4 of the die pad 31; wire bonding the sensor chip 2 to, for example, another semiconductor chip 7; and molding the sensor chip 2, the die pad 31, and the inner leads 32 by using the resin encapsulating material 9.

Regularly, in the step of die-bonding the sensor chip 2, the sensor chip 2 is die-bonded to the pad support portion 43 and the opposite-side support portion 44. Thereby, the sensor chip 2 is steadily supported till the step of molding.

In the step of molding, the resin encapsulating material 9 is filled into the clearance between the recess portion 5 and the sensor chip 2.

FIG. 8A shows a micro device 1 by way of a modified example of the above-described present embodiment, wherein instead of the recess portion 5, a cut-formed portion 6 is formed in the die pad 31. In this modified example, the contact portion 4 is formed into the same shape as that of the contact portion 4 shown in FIG. 7A. The cut-formed portion 6 is thus formed on the surface of the die pad 31. The cut-formed portion 6 may be formed by a known technique, such as punching, cutting, dry etching, or wet etching, for example.

FIG. 8B is a cross-sectional view of the micro device 1 shown along the line A-A of FIG. 8A after resin encapsulation. In the shown cross section, the sensor chip 2 is die-bonded to the pad support portion 43 and opposite-side support portion 44 of the die pad 31. The cut-formed portion 6 is filled with the resin encapsulating material 9.

As can be seen from FIG. 8B, the cut-formed portion 6 does not impose the thermal strain on the sensor chip 2, therefore rendering the performance of the sensor chip 2 to be more steady than the embodiment shown in FIG. 7A. In the present embodiment, however, the contact portion 4 is completely formed like a brattishing, thereby to reduce the strength of the lead frame. As such, in a step such as the step of die-bonding where a load is imposed on the lead frame, care should be taken in handling.

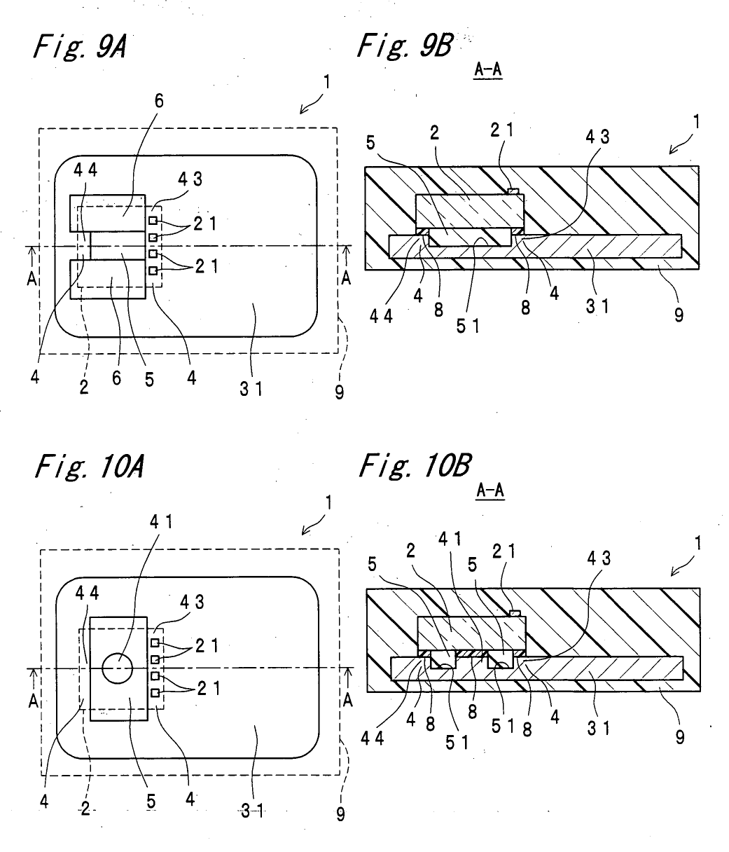

FIGS. 9A and 9B show another modified example of the micro device 1 of the above-described present embodiment. In the modified example, a non-contact portion has a combination feature of a recess portion 5 and cut-formed portions 6. In the non-contact portion, upper and lower portions are the cut-formed portions 6, and the recess portion 5 is formed between the cut-formed portions 6. Similar to the configurations shown in FIGS. 7A and 8A, the contact portion 4 is formed of the pad support portion 43 and the opposite-side support portion 44. A feature, among others, of the modified example is that, compared with the configuration in FIG. 7A, since the cut-formed portions 6 are disposed, the thermal-strain reduction effect is high. Another feature is that, compared with the configuration shown in FIG. 8A, since the recess portion 5 is disposed, the lead frame strength is high. More particularly, the recess portion 5 is preferably formed to continue to the opposite-side support portion 44. The opposite-side support portion 44 is formed into the projected cut piece, so that the opposite-side support portion 44 tends to be low in strength; however, the strength can be compensated for by forming the opposite-side support portion 44 in continuation to the recess portion 5.

The dispositions of the cut-formed portions 6 and the recess portion 5 in the non-contact portion are not limited to those in FIG. 6A. For example, the configuration may be such that the cut-formed portions 6 are formed in left and right portions in the horizontal direction, and the recess portion 5 is formed between the cut-formed portions 6. Alternatively, the configuration may be such that the cut-formed portions 6 and the recess portion 5 are disposed in a stripe state. Still alternatively, the configuration may be such that recess portions 5 are formed along the vertical and horizontal directions in a lattice state, wherein a region surrounded by the recess portions 5 is used as a cut-formed portion 6.

Fourth Embodiment

FIG. 10A is view of a fourth embodiment of the semiconductor micro device according to the present invention. More specifically, FIG. 10A mainly shows configurations of a sensor chip 2 and a die pad 31, wherein a semiconductor chip 7 and inner leads 32 are not shown. The sensor chip 2 used in the present embodiment is shaped to be electrically communicable with another semiconductor chip 7 by wire bonding, as in the case of FIG. 1A. In the shown sensor chip 2, four bonding pads 21 for wire bonding are formed on the upper surface of the sensor chip 2 along one side of the rectangle whereon the sensor chip 2.

A contact portion 4 for supporting the sensor chip 2 and a recess portion 5 formed by etching about half the thickness of the die pad 31 are formed on the surface of the die pad 31. The contact portion 4 is constituted of three portions. A first portion is a pad support portion 43 that supports a bottom portion of one side (right side of the chip, as viewed in FIG. 10A), along which the bonding pads 21 are formed, of four sides forming the edge portion of the sensor chip 2. A second portion is an opposite-side support portion 44 for supporting a bottom portion of an opposite side (left side of the chip, as viewed in FIG. 10A) opposing the above-described one side of the sensor chip 2. A third portion is a circular center support portion 41 positioned in the center of the sensor chip 2.

The pad support portion 43 is capable of supporting stresses being imposed on the bonding pads 21 of the sensor chip 2, therefore enabling suppressing an event where the chip is tilted by stresses occurring during wire bonding.

In cooperation with the pad support portion 43, the opposite-side support portion 44 and the center support portion 41 steadily support the sensor chip 2 in the duration from die-bonding of the sensor chip 2 to the molding process.

The center support portion 41 is effective to prevent the sensor chip 2 from being arcuately bent. The present embodiment is especially suited for use in a case where the sensor chip 2 is sized relatively large, and the sensor chip 2 tends to easily be arcuately bent as the thickness thereof is small. Although the center support portion 41 is formed circular in the present embodiment, the center support portion 41 may be formed into an arbitrary shape such as a polygonal shape like a rectangular shape, or an elliptical shape.

The recess portion 5 is formed in a region excepting the contact portion 4 between the pad support portion 43 and opposite-side support portion 44 of the die pad 31. The recess portion 5 may be formed by using a known technique, such as dry etching or wet etching.

In the configuration shown in FIG. 10A, there are formed the recess portion 5, which has a substantially rectangular profile, and the center support portion 41, which is formed in the substantially center of the recess portion 5. The form width of the recess portion 5, that is, the distance between the pad support portion 43 and the opposite-side support portion 44, is set smaller than the form width of the sensor chip 2. Thereby, left and right edge portions of the sensor chip 2 can be die-bonded and secured thereby to the pad support portion 43 and the opposite-side support portion 44. The form length of the recess portion 5 is preferably set larger than the form length of the sensor chip 2. In the configuration thus formed, the upper and lower sides of the sensor chip 2 and the clearance from the die pad 31 can be set relatively longer, so that the thermal strain being potentially being imposed on the sensor chip 2 can be even more reduced.

As is shown in FIG. 10A, when observed from over the die pad 31, partial sections of the recess portion 5 are seen in outer portions of the upper and lower sides of the sensor chip 2. In molding, the resin encapsulating material 9 feeds in the recess portion 5 from clearance between the recess portion 5 and the sensor chip 2, whereby to fill the region between the recess portion 5 and the sensor chip 2.

The recess portion 5 may be formed by using a known technique, such as dry etching or wet etching.

In the present embodiment, although the single center support portion 41 is formed in the center of the recess portion 5, no limitations are imposed. For example, a plurality of center support portions 41 each having a small area may be formed to be apart from one another. These center support portions 41 are preferably disposed to facilitate balancing of the sensor chip 2.

FIG. 10B is a cross-sectional view taken along the line A-A of the micro device of FIG. 10A after resin encapsulation. In the shown cross section, the sensor chip 2 is die-bonded to the pad support portion 43, opposite-side support portion 44, and center support portion 41 of the die pad 31. The recess portion 5 is filled with the resin encapsulating material 9.

With reference to FIG. 10B, as the depth of the respective recess portion 5 is larger, the thickness of the resin encapsulating material 9 interposed between the bottom portion 51 of the recess portion 5 and the sensor chip 2 is proportionally larger. As the thickness of the resin encapsulating material 9 is larger, the relief degree of the thermal strain potentially transferring to the sensor chip 2 from a bottom portion 51 is proportionally larger. Accordingly, as the depth of the recess portion 5 is larger, the effect of reducing the thermal strain potentially imposed thereon is proportionally enhanced. However, with an increased depth of the recess portion 5, the time and costs required for etching are increased. It is preferable that the depth of the respective recess portion 5 be set to fall within a tolerable range of thermal strain potentially imposed on the chip.

A manufacturing process for the semiconductor micro device according to the present invention includes: forming a predetermined recess portion 5 and a predetermined support portion 4 on a die pad 31 of a wire frame; wire bonding a sensor chip 2 to a part or the entirety of the contact portion 4 of the die pad 31; wire bonding the sensor chip 2 to, for example, another semiconductor chip 7; and molding the sensor chip 2, the die pad 31, and the inner leads 32 by using the resin encapsulating material 9.

At the step of die-bonding the sensor chip 2, in the sensor chip 2, at least two of the three support portions (4) are each formed with a die pad. Particularly, the pad support portion 43 is preferably formed with a die pad. Thereby, the sensor chip 2 can be more steadily held in the step of wire bonding.

As an example combination of the support portions to be die-bonded, any one may be selected from a method of die-bonding to the pad support portion 43 and the center support portion 41, a method of die-bonding to the pad support portion 43 and the center support portion 41, and a method of die-bonding to the pad support portion 43, the opposite-side support portion 44, and the center support portion 41. In any of the methods of combinations, the sensor chip 2 is steadily supported in duration till the step of molding.

In the step of molding, the resin encapsulating material 9 is filled into the clearance between the recess portion 5 and the sensor chip 2.

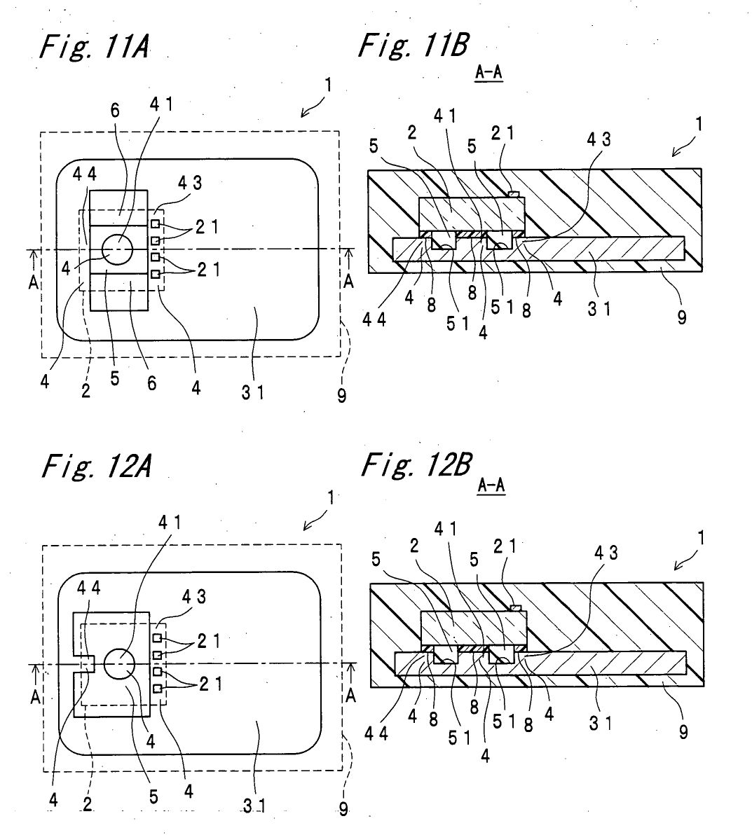

FIG. 11A shows a modified example of the micro device 1 of the above-described present embodiment. In this modified example, a non-contact portion has a combination feature of a recess portion 5 and cut-formed portions 6. A center support portion 41 is formed in a part of the recess portion 5. In a non-contact portion, the upper and lower portions are the individual cut-formed portions 6, and the recess portion 5 is formed between the cut-formed portions 6. The cut-formed portions 6 may be formed by a known technique, such as punching, cutting, dry etching, or wet etching, for example. Similar to the case shown in FIGS. 10A and 10B, the contact portion 4 is configured of the pad support portion 43, the opposite-side support portion 44, the center support portion 41.

FIG. 11B is a cross-sectional view of the micro device 1 shown along the line A-A of FIG. 11A after resin encapsulation. In the shown cross section, the sensor chip 2 is die-bonded to the pad support portion 43, opposite-side support portion 44, and opposite-side support portion 44 of the die pad 31. The cut-formed portions 6 are filled with the resin encapsulating material 9.

A feature, among others, of the modified example shown in FIG. 11A is that, compared with the configuration in FIG. 10A, since the cut-formed portions 6 are disposed, the thermal-strain reduction effect is high.

The dispositions of the cut-formed portions 6 and the recess portion 5 in the non-contact portion are not limited to those in FIG. 11A. For example, the configuration may be such that the cut-formed portions 6 are formed in left and right portions in the horizontal direction, and the recess portion 5 is formed between the cut-formed portions 6. Alternatively, the configuration may be such that the cut-formed portions 6 and the recess portion 5 are disposed in a stripe state. Still alternatively, the configuration may be such that recess portions 5 are formed along the vertical and horizontal direction in a lattice state, wherein a region surrounded by the recess portions 5 is used as a cut-formed portion 6.

Fifth Embodiment

FIG. 12A is view of a fifth embodiment of the semiconductor micro device according to the present invention. More specifically, FIG. 12A mainly shows configurations of a sensor chip 2 and a die pad 31, wherein a semiconductor chip 7 and inner leads 32 are not shown. The sensor chip 2 used in the present embodiment is shaped to be electrically communicable with another semiconductor chip 7 by wire bonding, as in the case of FIG. 1A. In the shown sensor chip 2, four bonding pads 21 for wire bonding are formed on the upper surface of the sensor chip 2 along one side of the rectangle whereon the sensor chip 2.

A contact portion 4 for supporting the sensor chip 2 and a recess portion 5 formed by etching about half the thickness of the die pad 31 are formed on the surface of the die pad 31.

The contact portion 4 is constituted of three portions. A first portion is a pad support portion 43 that supports a bottom portion of one side (right side of the chip, as viewed in FIG. 12A), along which the bonding pads 21 are formed, of four sides forming the edge portion of the sensor chip 2. A second portion is an opposite-side support portion 44 for supporting only a substantially central portion of a bottom portion of an opposite side (left side of the chip, as viewed in FIG. 12A) opposing the above-described one side of the sensor chip 2. A third portion is a circular center support portion 41 positioned in the center of the sensor chip 2.

The pad support portion 43 is capable of supporting stresses being imposed on the bonding pads 21 of the sensor chip 2, therefore suppressing an event where the chip is tilted by stresses occurring during wire bonding.

In cooperation with the pad support portion 43, the opposite-side support portion 44 and the center support portion 41 steadily support the sensor chip 2 in the duration from die-bonding of the sensor chip 2 to the molding process.

The center support portion 41 is effective to prevent the sensor chip 2 from being arcuately bent. The present embodiment is especially suited for use in a case where the sensor chip 2 is sized relatively large, and the sensor chip 2 tends to easily be arcuately bent as the thickness thereof is small. Although the center support portion 41 is formed circular in the present embodiment, the center support portion 41 may be formed into an arbitrary shape such as a polygonal shape like a rectangular shape, or an elliptical shape.

The opposite-side support portion 44 according to the present embodiment is formed to have a smaller area as compared to the embodiment shown in FIG. 10A. However, while steady-supporting capability is somewhat reduced, the thermal strain potentially imposed on the sensor chip 2 can be lowered.

In the configuration shown in FIG. 12A, the recess portion 5 has a profile wherein a small, substantially rectangular projection portion (opposite-side support portion 44) is formed on the left side of a substantially rectangular shape. A minimum form width (minimum horizontal width) of the recess portion 5, that is, the distance between the pad support portion 43 and the opposite-side support portion 44, is set smaller than the form width the sensor chip 2. Thereby, left and right edge portions of the sensor chip 2 can be die-bonded and secured thereby to the pad support portion 43 and the opposite-side support portion 44. The maximum form width of the recess portion 5 is a form width in the case where the opposite-side support portion 44 is excluded. In the case shown in FIG. 12A, a maximum form width of the recess portion 5 is set substantially identical to the chip form width. However, a maximum form width is not limited thereto. In the event of die-bonding of the sensor chip 2, the maximum form width may be altered so that a portion of the left side section of the recess portion 5, in which the opposite-side support portion 44 is not formed, is spaced away from the sensor chip 2. In the configuration thus formed, the left side of the sensor chip 2 and the die pad 31 can partly be spaced away from each other, so that the thermal strain potentially imposed on the sensor chip 2 can be even more reduced.

The form length (vertical length) of the recess portion 5 is preferably set larger than the form length of the sensor chip 2. In the configuration thus formed, the upper and lower sides of the sensor chip 2 the clearance from the die pad 31 can be set relatively longer, so that the thermal strain being- potentially being imposed can be even more reduced.

As is shown in FIG. 12A, as observed from over the die pad 31, partial sections of the recess portion 5 (sections not in contact with the opposite-side support portion 44) are seen in outer portions of the upper and lower sides of the sensor chip 2. In molding, the resin encapsulating material 9 feeds in the recess portion 5 from clearance between the recess portion 5 and the sensor chip 2, whereby to fill the region between the recess portion 5 and the sensor chip 2.

The recess portion 5 may be formed by a known technique, such as dry etching or wet etching, for example.

Although the single center support portion 41 is formed in the center of the recess portion 5, no limitations are imposed. For example, a plurality of center support portions 41 each having a small area may be formed to be apart from one another. These center support portions 41 are preferably disposed to facilitate balancing of the sensor chip 2.

FIG. 12B is a cross-sectional view taken along the line A-A of the micro device of FIG. 12A after resin encapsulation. In the shown cross section, the sensor chip 2 is die-bonded to the pad support portion 43, opposite-side support portion 44, and center support portion 41 of the die pad 31. The recess portion 5 is filled with the resin encapsulating material 9.

With reference to FIG. 12B, as the depth of the respective recess portion 5 is larger, the thickness of the resin encapsulating material 9 interposed between the bottom portion 51 of the recess portion 5 and the sensor chip 2 is proportionally larger. As the thickness of the resin encapsulating material 9 is larger, the relief degree of the thermal strain potentially transferring to the sensor chip 2 from a bottom portion 51 is proportionally larger. Accordingly, as the depth of the recess portion 5 is larger, the effect of reducing the thermal strain potentially imposed thereon is proportionally enhanced. However, with an increased depth of the recess portion 5, the time and costs required for etching are increased. It is preferable that the depth of the respective recess portion 5 be set to fall within a tolerable range of the thermal strain potentially imposed on the chip.

A manufacturing process for the semiconductor micro device according to the present invention includes: forming a predetermined recess portion 5 and a predetermined support portion 4 on a die pad 31 of a wire frame; wire bonding a sensor chip 2 to a part or the entirety of the contact portion 4 of the die pad 31; wire bonding the sensor chip 2 to, for example, another semiconductor chip 7; and molding the sensor chip 2, the die pad 31, and the inner leads 32 by using the resin encapsulating material 9.

At the step of die-bonding the sensor chip 2, in the sensor chip 2, at least two of the three support portions (4) are each formed with a die pad. Particularly, the pad support portion 43 is preferably formed with a die pad. Thereby, the sensor chip 2 can be more steadily held in the step of wire bonding.

As an example combination of the support portions to be die-bonded, any one may be selected from a method of die-bonding to the pad support portion 43 and the center support portion 41, a method of die-bonding to the pad support portion 43 and the center support portion 41, and a method of die-bonding to the pad support portion 43, the opposite-side support portion 44, and the center support portion 41. In any of the methods of combinations, the sensor chip 2 is steadily supported in duration till the step of molding.

In the step of molding, the resin encapsulating material 9 is filled into the clearance between the recess portion 5 and the sensor chip 2.

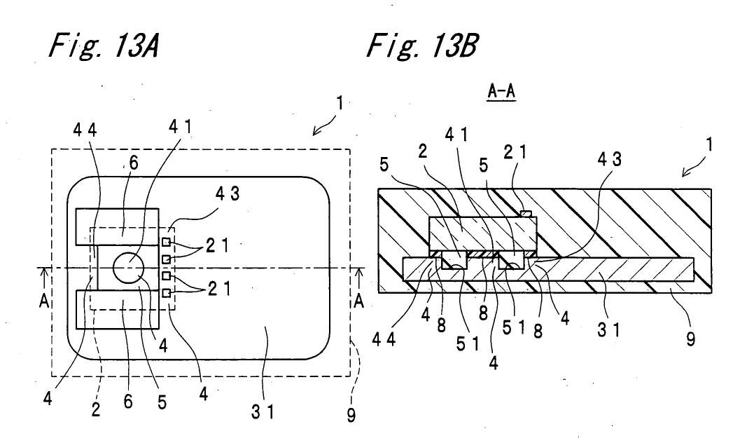

FIG. 13A shows a modified example of the micro device 1 of the above-described present embodiment. In this modified example, a non-contact portion has a combination feature of a recess portion 5 and cut-formed portions 6. A center support portion 41 is formed in a part of the recess portion 5. In a non-contact portion, the upper and lower portions are the individual cut-formed portions 6, and the recess portion 5 is formed between the cut-formed portions 6. The cut-formed portions 6 may be formed by a known technique, such as punching, cutting, dry etching, or wet etching, for example. Similar to the case shown in FIGS. 12A and 12B, the contact portion 4 is configured of the pad support portion 43, the opposite-side support portion 44, and the center support portion 41.

FIG. 13B is a cross-sectional view of the micro device 1 shown along the line A-A of FIG. 13A after resin encapsulation. In the shown cross section, the sensor chip 2 is die-bonded to the pad support portion 43, opposite-side support portion 44, and opposite-side support portion 44 of the die pad 31. The cut-formed portions 6 are filled with the resin encapsulating material 9.

A feature, among others, of the modified example shown in FIG. 13A is that, compared with the configuration in FIG. 12A, since the cut-formed portions 6 are disposed, the thermal-strain reduction effect is high. More particularly, the recess portion 5 is preferably formed to continue to the opposite-side support portion 44. The opposite-side support portion 44 is formed into the projected cut piece, so that the opposite-side support portion 44 tends to be low in strength; however, the strength can be compensated for by forming the opposite-side support portion 44 in continuation to the recess portion 5.

The dispositions of the cut-formed portions 6 and the recess portion 5 in the non-contact portion are not limited to those in FIG. 13A. For example, the configuration may be such that the cut-formed portions 6 are formed in left and right portions in the horizontal direction, and the recess portion 5 is formed between the cut-formed portions 6. Alternatively, the configuration may be such that the cut-formed portions 6 and the recess portion 5 are disposed in a stripe state. Still alternatively, the configuration may be such that recess portions 5 are formed along the vertical and horizontal direction in a lattice state, wherein a region surrounded by the recess portions 5 is used as a cut-formed portion 6.

Although the present invention has thus been described and shown in conjunction with the preferred embodiments and the accompanying drawings, various modifications and alterations may be -obvious to those skilled in the art. It is to be understood that such modifications and alterations are within the spirit and scope of the invention as defined by the appended claims.

1. A semiconductor micro device comprising:
a rectangular silicon micro structure chip;
a lead frame having a die pad for securing the silicon structure chip, said die pad comprising a contact portion being in contact with the silicon structure chip; and
a resin encapsulating material for encapsulating the silicon structure chip and part of the lead frame;
wherein the die pad of the lead frame has a non-contact portion positioned lower than the contact portion not to be in contact with the silicon structure chip, the non-contact portion being formed at least in a position corresponding to a diagonal portion of the silicon structure chip,
a clearance between the non-contact portion and the silicon structure chip being filled with the resin encapsulating material, whereby the die pad and the silicon structure chip are bonded to each other by the resin encapsulating material.

2. The semiconductor micro device according to claim 1, wherein
the non-contact portions are formed at least in positions corresponding to each of four corner portions of the silicon structure chip.

3. The semiconductor micro device according to claim 1, wherein
the non-contact portion is formed at least in a position corresponding to a central portion of the silicon structure chip.

4. The semiconductor micro device according to claim 1, wherein
the non-contact portion comprises a recess portion formed in the die pad.

5. The semiconductor micro device according to claim 1, wherein
the non-contact portion comprises a cut-formed portion opening in the die pad.

6. The semiconductor micro device according to claim 1, wherein
the silicon structure chip has a bonding pad for wire bonding, and
the non-contact portion is not formed in a position corresponding to the bonding pad.
